(19) United States
(12) Patent Application Publication
(10) Pub. No.: US 2015/0371850 A1
(43) Pub. Date: Dec. 24, 2015

(54) METHOD OF FORMING SEMICONDUCTOR THIN FILM

(71) Applicants: NAGOYA UNIVERSITY, NATIONAL UNIVERSITY CORPORATION, Aichi (JP); KYUSHU UNIVERSITY, NATIONAL UNIVERSITY CORPORATION, Fukuoka (JP); GIGAPHOTON INC., Tochigi (JP)

(72) Inventors: Masashi KUROSAWA, Aichi (JP); Noriyuki TAOKA, Aichi (JP); Osamu NAKATSUKA, Aichi (JP); Shigeaki ZAIMA, Aichi (JP); Hiroshi IKENOUE, Fukuoka (JP)

(73) Assignees: NAGOYA UNIVERSITY, NATIONAL UNIVERSITY CORPORATION, Aichi (JP); GIGAPHOTON INC., Tochigi (JP); KYUSHU UNIVERSITY, NATIONAL UNIVERSITY CORPORATION, Fukuoka (JP)

(21) Appl. No.: 14/839,290

(22) Filed: Aug. 28, 2015

Related U.S. Application Data
(63) Continuation of application No. PCT/JP2014/054515, filed on Feb. 25, 2014.

(30) Foreign Application Priority Data
Mar. 5, 2013 (JP) 2013-042775

(51) Int. Cl. H01L 21/02

(52) U.S. Cl. CPC H01L 21/02686; H01L 21/02532; H01L 21/02422; H01L 21/02535

(57) ABSTRACT

Provided is a method of forming a semiconductor thin film. The method may include forming, on a substrate, a thin film that contains one of Ge, Si, and a SiGe mixture, and Sn in a content of 0.1 atomic % or more to 20 atomic % or less, and applying pulsed laser light to the thin film.

### CROSS REFERENCE TO RELATED APPLICATIONS

This is a continuation of International Application No. PCT/JP2014/054515, filed Feb. 25, 2014, which claims the benefit of Japanese Priority Patent Application JP2013-042775, filed Mar. 05, 2013, the entire contents of both of which are incorporated herein by reference.

### BACKGROUND

The disclosure relates to a method of forming a semiconductor thin film. A semiconductor thin film has been used for numerous electric and electronic devices, not only as a channel material of a transistor that serves as a basis device of a large-scale integrated circuit, a flat-panel display, etc., but even as a light absorbing material of a solar cell. Currently, main materials for such electric and electronic devices are Group IV semiconductors, especially silicon (Si) which is considered as the mainstream among the Group IV semiconductors. Up to now, improvement in device performance has been achieved continuously for semiconductors that use Si or the like, from the viewpoint of improving a device structure such as, but not limited to, miniaturization and surface texture. For example, reference is made to Japanese Unexamined Patent Application Publication No. 2007-109943. The device performance, however, faces a limit as a result of dependency on physical properties of Si itself, such as, but not limited to, carrier mobility and light absorption coefficient. A development of semiconductor materials other than Si has therefore been started actively, some examples of which may include a Group III-V semiconductor, an oxide semiconductor, and an organic semiconductor. Nevertheless, Si still maintains its overwhelming superiority as a semiconductor material in terms of reliability in operation of a transistor, a solar cell, etc. Non-limiting examples of the operation reliability may include reliability in P-type or N-type doping control and reliability in threshold voltage control.

Under such circumstances, germanium (Ge) is a recent promising candidate for a new material that replaces Si. Ge is the same Group IV element as Si, but features higher carrier mobility, including electron mobility and hole mobility, and larger light absorption coefficient than those of Si. Hence, demonstration experiments have been actively carried out on high-speed operation of a transistor in which Ge is used as a channel material. For example, reference is made to K. Morii et al., IEEE Electron Device Letters, Vol. 31, 2010, p. 1092 and C. H. Lee et al., IEDM Technical Digest, San Francisco, USA, 2010, p. 417.

Studies have been also made on addition of tin (Sn) to a semiconductor thin film. Sn is the same Group W element as Si and Ge, and a significant improvement in physical properties of Group IV semiconductors, such as, but not limited to, carrier mobility and light absorption coefficient, is expected by the addition of Sn, according to the theoretical calculation disclosed in P. Moontragoon et al., Semiconductor Science and Technology, Vol. 22, No. 7, 2007, p. 742. In fact, the inventors discovered a possibility of suppressing a density of point defect, which has been considered to be a problem unique to Ge, by the addition of Sn into Ge, as disclosed in O. Nakatsuka et al., Japanese Journal of Applied Physics, Vol. 49, No. 4, 2010, P. 04DA10.

To fully utilize features of a SiₓGe_{y}Sn_{11-x-y} semiconductor made of such Group IV elements (such as Si, Ge, and Sn), a crystal growth on an amorphous substrate such as, but not limited to, a glass substrate and a plastic substrate is also important. M. Kurosawa et al., Applied Physics Letters, Vol. 101, No. 9, 2012, p. 091905 (hereinafter referred to as “Non-Patent Document 5”) disclose that a growth of a GeSn thin film that involves an Sn concentration gradient of 0.1 to 0.4%/μm % in a lateral direction is achieved on a Si substrate covered with an amorphous (silicon dioxide (SiO₂)) film, with use of a melt growth method in a state of thermal equilibrium.

In order to form a film on a glass substrate that involves low resistance to heat, studies have also been made on a crystal growth in a low-temperature process, specifically, a crystal growth at a temperature of 500° C. or lower. W. Takeuchi et al., Extended Abstracts of the 2012 International Conference on Solid State Devices and Materials, Kyoto, 2012, p. 739 (hereinafter referred to as “Non-Patent Document 6”) discloses that, by adding 0.2% to 2% of Sn to a Ge film, lowering of a temperature in a solid-phase growth is possible as compared with a case in which no Sn is added. Also, Kurosawa et al., Proceedings of the 73th JSAP Meeting, Ehime, 2012, pp. 13-146 (hereinafter referred to as “Non-Patent Document 7”) discloses that lowering of a temperature in a crystallization process down to about 200° C. is possible by applying a thermal treatment (a metal-induced solid phase growth) that utilizes a eutectic reaction in a state of non-thermal equilibrium of Sn—Ge.

### SUMMARY

In general, there is a trade-off relationship between crystallinity of a semiconductor thin film and a temperature of a thermal treatment, making it extremely difficult to achieve a high-quality semiconductor thin film with use of a low temperature film-forming method. For example, the method disclosed in the Non-Patent Document 5 makes it possible to achieve a high-quality Group IV semiconductor crystal, but prevents such a high-quality Group IV semiconductor crystal from being formed on a glass substrate or a resin substrate, due to the requirement of a thermal treatment at a temperature at which Ge melts (938° C.) or higher. Non-limiting examples of such a resin substrate may include a polyethylene naphthalate (PEN) substrate, a polyethylene terephthalate (PET) substrate, a polyimide (PI) substrate, and a polycarbonate (PC) substrate.

Also, the methods disclosed in Non-Patent Documents 6 and 7 each involves a relatively low temperature process in which a film-forming temperature ranges from 200° C. to 500° C., making it possible to form a film on a glass substrate or a resin substrate, but making it extremely difficult to achieve a high-quality semiconductor thin film as disclosed in Non-Patent Document 5.

What is desired is a method of forming a semiconductor thin film that contains one of Ge, Si, and a SiGe mixture and involves high crystallinity, and makes it possible to form the semiconductor thin film on a substrate that involves low resistance to heat.

A method of forming a semiconductor thin film according to an embodiment of the disclosure may include forming, on a substrate, a thin film that contains one of Ge, Si, and a SiGe mixture, and Sn in a content of 0.1 atomic % or more to 20 atomic % or less, and applying pulsed laser light to the thin film.

### BRIEF DESCRIPTION OF THE DRAWINGS

Some embodiments of the disclosure are described below as mere examples with reference to the accompanying drawings.

FIGS. 1A to 1C each illustrates a process in a method of forming a semiconductor thin film according to an example embodiment of the disclosure.

FIG. 2 illustrates a structure of a laser irradiating apparatus that may form the semiconductor thin film according the example embodiment of the disclosure under pure water.

FIG. 3 illustrates a correlation of laser fluence versus a crystallization rate.

FIG. 4 illustrates a correlation of the laser fluence versus a crystal grain size.

FIG. 5 illustrates a correlation of the laser fluence versus a content of Sn in a composition in each polycrystal.

FIG. 6 illustrates a correlation of a content of Sn in a composition in each Ge thin film and the laser fluence versus crystal phases in air.

FIG. 7 illustrates a correlation of a content of Sn in a composition in each Ge thin film and the laser fluence versus crystal phases under pure water.

### DETAILED DESCRIPTION

In the following, some example embodiments of the disclosure are described in detail with reference to the drawings. Example embodiments described below each illustrates one example of the disclosure and are not intended to limit the contents of the disclosure. Also, all of the configurations and operations described in each example embodiment are not necessarily essential for the configurations and operations of the disclosure. Note that the like elements are denoted with the same reference numerals, and any redundant description thereof is omitted.

### [Method of Forming Semiconductor Thin Film]

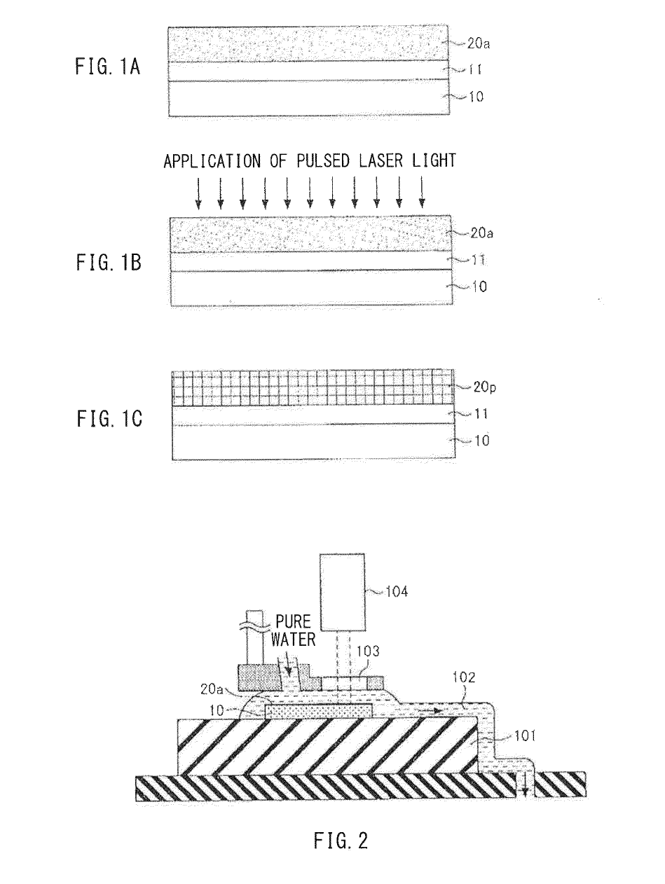

A description is given of a method of forming a semiconductor thin film according to an embodiment with reference to FIGS. 1A to 1C.

Referring to FIG. 1A, a silicon oxide film 11 may be first formed on a substrate 10 using a method such as, but not limited to, chemical vapor deposition (CVD), following which a Ge thin film 20a added with Sn may be formed on the silicon oxide film 11. More specifically, a silicon substrate serving as the substrate 10 and formed with the silicon oxide film 11 may be subjected to chemical cleaning, following which the cleaned silicon substrate formed with the silicon oxide film 11 may be placed in a vacuum deposition apparatus and a temperature of the substrate may be adjusted to a room temperature to form the Sn-added Ge thin film 20a. Besides the vacuum deposition, a deposition method of the Sn-added Ge thin film 20a may be any method such as, but not limited to, sputtering and chemical vapor phase epitaxy. Also, in the illustrated example embodiment, the silicon substrate may be used as the substrate 10. However, a glass substrate or any resin substrate may be used as the substrate 10. Non-limiting examples of the resin substrate may include a PEN substrate, a PET substrate, a PI substrate, and PC substrate. Also, any other film such as, but not limited to, a silicon nitride (SiN) film and a multilayer film including a silicon oxide film and a silicon nitride film may be used instead of the silicon oxide film 11.

The thus-formed Sn-added Ge thin film 20a may be formed under condition in which the substrate is at the room temperature, and may be thus amorphous. The formed Sn-added Ge thin film 20a may preferably contain Sn in a content of 0.1 atomic % or more to 20 atomic % or less in a composition. A thickness of the Sn-added Ge thin film 20a may preferably be in a range from 10 nm to 1 μm, and may more preferably be in a range from 20 nm to 200 nm. In the example embodiment, a thickness of the formed Sn-added Ge thin film 20a may be about 50 nm.

Referring next to FIG. 1B, the Sn-added Ge thin film 20a may be irradiated with pulsed laser light, i.e., the pulsed laser light may be applied to the Sn-added Ge thin film 20a. More specifically, the substrate 10 including the thus-formed silicon oxide film 11 and Sn-added Ge thin film 20a may be placed in a laser irradiation apparatus to perform the application of the pulsed laser light. Irradiating the Sn-added Ge thin film 20a with the pulsed laser light in this way may melt the Sn-added Ge thin film 20a instantaneously. Cooling the thus-melted Sn-added Ge thin film 20a thereafter may crystallize the Sn-added Ge thin film 20a as illustrated in FIG. 1C to form a Ge thin film 20p added with Sn. A crystal phase of the thus-crystallized Sn-added Ge thin film 20p may be a polycrystalline phase, allowing the Sn-added Ge thin film 20p to serve as a semiconductor thin film. In the example embodiment, a beam shape and a pulse width of the pulsed laser light to be applied may respectively be about 360×850 μm² and about 55 ns without limitation.

To increase a grain size of crystals in the Sn-added Ge thin film 20p, the Sn-added Ge thin film 20a may be preferably at a temperature equal to or higher than a melting point of the Sn-added Ge thin film 20a upon the application of the pulsed laser light to the Sn-added Ge thin film 20a. Also, an atmosphere under which the substrate 10 formed with the Sn-added Ge thin film 20a is placed upon the application of the pulsed laser light may be, for example but not limited to, air, inert gas, vacuum, or pure water. Non-limiting examples of the inert gas may include nitrogen and argon.

### [Application of Pulsed Laser Light Under Pure Water]

A description is given next, based on FIG. 2, of a method of applying the pulsed laser light to the Sn-added Ge thin film 20a formed on the substrate 10, or on any other suitable member, under the pure water. A laser irradiation apparatus illustrated in FIG. 2 may be used when applying the pulsed laser light to the Sn-added Ge thin film 20a formed on the substrate 10, or on any other suitable member, under the pure water. More specifically, the substrate 10 formed with the Sn-added Ge thin film 20a may be placed on an XY stage 101, and pure water 102 may be so fed as to cover the substrate 10 formed with the Sn-added Ge thin film 20a. While the pure water 102 may be fed in this way, the pulsed laser light may be applied from a laser light source 104 through a quartz window 103 to the Sn-added Ge thin film 20a.

### [Experimental Results]

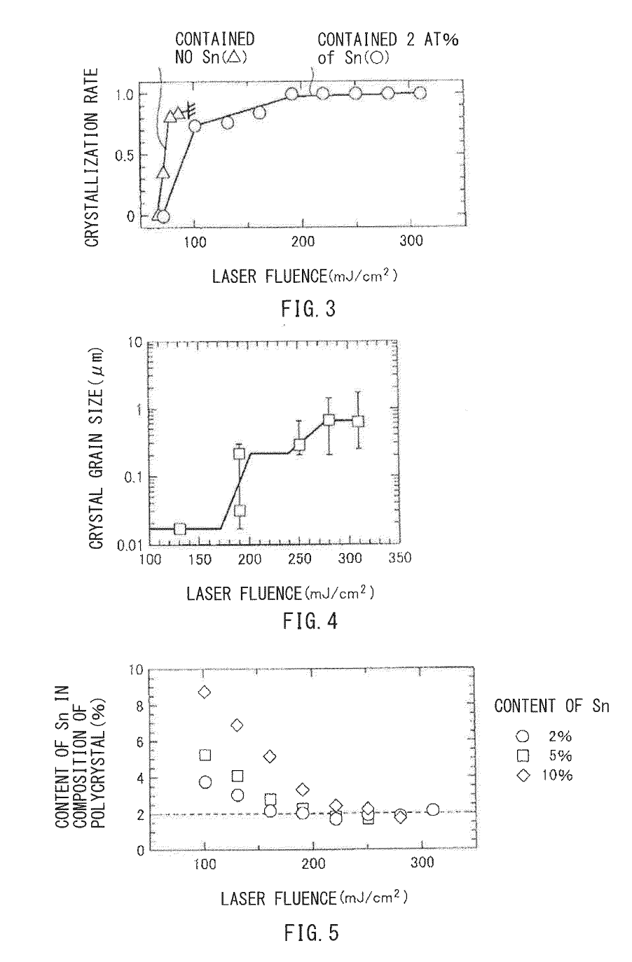

A description is given next of experimental results of the method of forming the semiconductor thin film according to the example embodiment, where factors, including application conditions of the pulsed laser light to be applied to the Sn-added Ge thin film 20a and a content of Sn in each composition thereof, were varied. FIGS. 3 to 5 each illustrates the experimental results that were derived from the application of the pulsed laser light under the pure water as illustrated in FIG. 2.

First, a description is given, based on FIG. 3, of an influence of addition of Sn to the Ge thin film. FIG. 3 illustrates a relationship of fluence, or “laser fluence”, of the pulsed laser light applied to the Sn-added Ge thin film 20a versus a crystallization rate. The crystallization rate here was a value determined based on an area ratio of the area of a crystal component to the entire area of amorphous and crystal components. The amorphous component and the crystal component were derived from separation of a spectrum, obtained by micro-Raman spectroscopy, into a spectrum belonging to the amorphous component and a spectrum belonging to the crystal component.

Referring to FIG. 3, a Ge thin film with no addition of Sn (contained no Sn) and a Ge thin film with addition of 2 atomic % of Sn (contained 2 atomic % of Sn) both involved higher crystallization rate with an increase in the laser fluence. In a case of the Ge thin film with no addition of Sn (contained no Sn), the crystallization rate was increased up to 0.85 where the laser influence was 85 mJ/cm². However, the laser fluence exceeding 85 mJ/cm² caused agglomeration of Ge which prevented the crystallization rate from reaching 1.0.

In contrast, in a case of the Ge thin film with the addition of 2 atomic % of Sn (contained 2 atomic % of Sn), the crystallization rate was 1.0 where the laser influence was in a range from 190 mJ/cm² to 300 mJ/cm².

This means that the addition of Sn to the Ge thin film makes it possible to suppress a damage of the thin film attributed to the laser application, and to increase an upper limit of the laser fluence. The increase in the laser fluence in turn promotes crystallization of the thin film. As used herein, the wording “damage of the thin film attributed to the laser application” may refer to, for example but not limited to, a state in which a form of a film is unmaintained due to agglomeration of Ge.

Note that the promotion of the crystallization by means of the addition of Sn to the Ge thin film was confirmed in both of the cases in which the laser light was applied in the air and the laser light was applied under the pure water, as described later in greater detail.

FIG. 4 illustrates results of examination on a relationship of the laser fluence versus a crystal grain size of polycrystal in the Ge thin film 20p with the addition of 2 atomic % of Sn (contained 2 atomic % of Sn). The crystal grain size was determined by an electron backscatter diffraction (EBSD) method. An increase in the laser influence increased the crystal grain size from about 0.01 μm up to about 1 μm, which is about 100 times greater than the crystal grain size of about 0.01 μm. One reason is that the addition of Sn to the Ge thin film made it possible to increase the laser fluence of the pulsed laser light to be applied.

FIG. 5 illustrates results of examination on a relationship of the laser fluence versus a content, in a composition, of Sn inside the polycrystal, where the content of Sn added to each Ge thin film was varied. More specifically, a Ge thin film added with 2 atomic % of Sn (contained 2 atomic % of Sn), a Ge thin film added with 5 atomic % of Sn (contained 5 atomic % of Sn), and a Ge thin film added with 10 atomic % of Sn (contained 10 atomic % of Sn) were fabricated as samples. The results were obtained as a result of applying the pulsed laser light to the thus-fabricated Sn-added Ge thin films. Note that the content, in a composition, of Sn inside the polycrytal was determined from a variation in a peak position of a Ge—Ge bond obtained by micro-Raman spectrometry. The application of laser light with high laser influence brought the content, in the composition, of Sn inside the polycrystal closer to about 2 atomic % in all of the fabricated Sn-added Ge thin films. This is presumably due to a solid solubility limit of Sn in Ge which is from 2 atomic % to 3 atomic %. Also, based upon FIG. 5, adjusting an amount of the addition of Sn to the Ge thin film and the laser influence makes it possible to adjust the content of Sn in the composition in the polycrystal to a desired content.

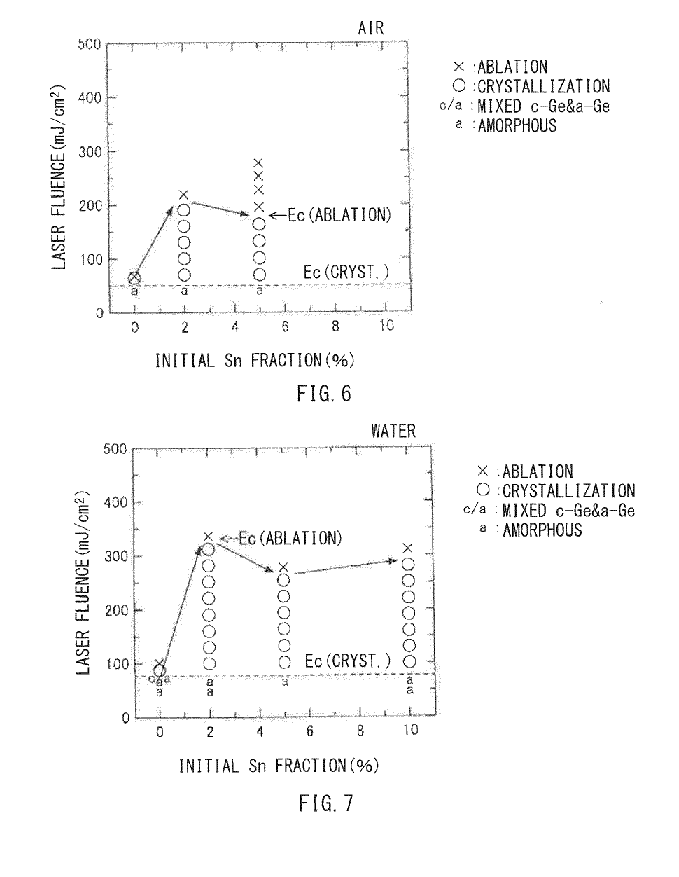

FIG. 6 illustrates a transformation of a crystallization phase upon the application of the pulsed laser light to Sn-added Ge thin films in the air. FIG. 7 illustrates a transformation of a crystallization phase upon the application of the pulsed laser light to Sn-added Ge thin films under the pure water. In FIGS. 6 and 7, “a” denotes an amorphous phase, “o” denotes a crystallization phase, i.e., denotes a polycrystalline phase, and “x” denotes that the damage, or ablation, is generated by the laser application. The addition of Sn in any of the cases performed in the air and under the pure water made it possible to increase a level of the laser fluence at which the damage attributed to the laser application is generated, and to promote the crystallization accordingly.

The inventors confirmed that the Sn content of 0.1 atomic % or greater in a composition made it possible to increase the level of the laser fluence at which the damage attributed to the laser application is generated. The inventors also confirmed that the Sn content of 20 atomic % or less in the composition made it possible to allow the Sn-added Ge thin film to be eutectic without causing segregation of Sn in the thin film. That means, adding Sn in the content of 0.1 atomic % or more to 20 atomic % or less in the Ge thin film makes it possible to increase a margin of the laser fluence of the pulsed laser light to be applied, and to perform the application of the pulsed laser light with the optimal laser fluence. Hence, it is possible to perform optimal annealing.

As illustrated in FIG. 6, an upper limit of the laser fluence was about 200 mJ/cm² when the laser application was performed in the air. In contrast, it was possible to increase the upper limit of the laser fluence up to about 300 mJ/cm² as illustrated in FIG. 7 when the laser application was performed under the pure water.

A description is given next of results of measurement of a surface roughness following the application of the pulsed laser light in the air and under the pure water. The measurement was performed using an atomic force microscope. The results of the measurement showed that the surface roughness was about 30 nm when the pulsed laser light was applied with the laser fluence of about 150 mJ/cm² in the air, whereas the surface roughness was about 10 nm when the pulsed laser light was applied with the laser fluence of about 300 mJ/cm² under the pure water. That means, the application of the pulsed laser light under the pure water makes it possible to reduce the surface roughness as compared with the application of the pulsed laser light in the air.

Hence, it is possible to further suppress the damage attributed to the laser application when the pulsed laser light is applied under the pure water, as compared with a case in which the application of the pulsed laser light is performed in the air, and thereby to form a film that involves higher flatness and higher crystallization rate. Hence, in the example embodiment, the pure water may be preferable, without limitation, over air as the atmosphere under which the pulsed laser light is applied. The application of the pulsed laser light under the pure water thus makes it possible to achieve a high-quality semiconductor thin film with superior surface flatness and crystallinity.

Also, the pulsed laser light is applied in the example embodiment, making it possible to heat only the Sn-added Ge thin film instantaneously. This in turn makes it possible to crystallize the Sn-added Ge thin film while hardly exerting an influence of heat generated by the application of the pulsed laser light on the substrate 10, etc. Hence, it is possible to use a substrate made of silica glass or any resin material that may be one of, for example but not limited to, PEN, PET, PC, PI, etc., in addition to silicon. The silica glass and the resin materials described above are transparent to light in a visible range, and may thus be used for application such as, but not limited to, a display. In general, those materials are low in resistance to heat and an annealing furnace or the like may not be used for crystallizing a Ge thin film upon annealing. In contrast, the thermal treatment in the example embodiment allows for annealing of the materials that involves low resistance to heat.

Also, the substrate 10 may include one of a semiconductor integrated circuit and a semiconductor device. For example, the substrate 10 may include a configuration in which the semiconductor integrated circuit or the semiconductor device is provided on a silicon substrate. One reason is that materials which are low in melting point, such as Al and a solder material, may be used for a wiring pattern and an electrode in the semiconductor integrated circuit or the semiconductor device and thus use of the annealing furnace or the like may not be preferable upon crystallizing the Ge thin film.

A thickness of the formed Sn-added Ge thin film 20a may be preferably in a range from 10 nm to 1 μm, and may more preferably be in a range from 20 nm to 200 nm. One reason is that a small thickness of the Sn-added Ge thin film 20a, for example but not limited to, smaller than 10 nm, may make it difficult to generate crystallization and may thus result in microcrystalline phase, and hence may prevent promotion of crystallization. Also, one reason is that a large thickness of the Sn-added Ge thin film 20a, for example but not limited to, larger than 1 μm, may result in crystallization only at a region near a surface of the thin film and may leave a deep region of the thin film as it is in its amorphous phase, and hence may prevent achievement of sufficient semiconductor characteristics.

A wavelength of the pulsed laser light to be applied to the Sn-added Ge thin film 20a may be preferably in a range from about 193 nm to about 532 nm. One reason is that a wavelength of the pulsed laser light shorter than about 193 nm may cause the applied laser light to be absorbed by the pure water and may thus prevent sufficient irradiation of the Sn-added Ge thin film 20a, and hence may result in failure in annealing. Also, one reason is that a wavelength of the pulsed laser light longer than about 532 nm may decrease efficiency in crystallization in the light irradiation annealing, for example.

Described above in the example embodiment is the Ge thin film added with Sn. However, the technology is also applicable, as one embodiment, to Si that is the same Group IV element as Ge. That means, the technology is applicable, as one embodiment, to a thin film that contains, for example but not limited to, one of Ge, Si, and a SiGe mixture in which Si and Ge are mixed, as long as Sn is added thereto. In other words, an effect of the example embodiment may be equal to an effect achieved by a semiconductor of SiₓGe_{y}Sn_{1-x-y} in which 0.001≦1−x−y≦0.2.

The method of forming the semiconductor thin film according to the foregoing example embodiment may perform the application of the pulsed laser light. Hence, it is possible to instantaneously apply heat energy only to the formed thin film. Also, in the method of forming the semiconductor thin film according to the foregoing example embodiment, the thin film that may contain one of Ge, Si, SiGe, etc., may be added with Sn in the content of 0.1 atomic % or more to 20 atomic % or less. Hence, it is possible to promote crystallization while preventing agglomeration in the thin film.

It is therefore possible to achieve a high-quality semiconductor thin film that contains a Group IV element such as, but not limited to, Ge and Si or a mixture such as, but not limited to, SiGe, and that involves high carrier mobility and superior surface flatness, without being limited to a substrate on which the semiconductor thin film is formed.

Also, the method of forming the semiconductor thin film according to the foregoing example embodiment may perform the application of the pulsed laser light under the pure water. In this case, heat generated by the application of the pulsed laser light thermally diffuses from a surface of the thin film to the pure water, making it possible to apply more heat energy to the thin film. Hence, it is possible to further promote the crystallization of the thin film.

It may be therefore possible to provide a method of forming a semiconductor thin film that contains one of Ge, Si, and a SiGe mixture and involves high carrier mobility and superior surface flatness, and makes it possible to form the semiconductor thin film on a substrate that involves low resistance to heat, such as, but not limited to, a glass substrate and a plastic substrate.

Furthermore, the technology encompasses any possible combination of some or all of the various embodiments described herein and incorporated herein.

It is possible to achieve at least the following configurations from the above-described example embodiments of the technology.

(1) A method of forming a semiconductor thin film, the method including:

forming, on a substrate, a thin film that contains one of Ge, Si, and a SiGe mixture, and Sn in a content of 0.1 atomic % or more to 20 atomic % or less; and applying pulsed laser light to the thin film.

(2) The method of forming the semiconductor thin film according to (1), wherein the applying of the pulsed laser light to the thin film transforms the thin film from an amorphous phase to a polycrystalline phase.
(3) The method of forming the semiconductor thin film according to (1) or (2), wherein the substrate includes a glass substrate.
(4) The method of forming the semiconductor thin film according to (1) or (2), wherein the substrate includes one of a semiconductor integrated circuit and a semiconductor device.
(5) The method of forming the semiconductor thin film according to (1) or (2), wherein the substrate includes one of polyethylene naphthalate, polyethylene terephthalate, polyimide, and polycarbonate.
(6) The method of forming the semiconductor thin film according to any one of (1) to (5), wherein the applying of the pulsed laser light to the thin film is performed under pure water.
(7) The method of forming the semiconductor thin film according to any one of (1) to (6), wherein a wavelength of the pulsed laser light is in a range from about 193 nanometers to about 532 nanometers.

The foregoing description is intended to be merely illustrative rather than limiting. It should therefore be appreciated that variations may be made in example embodiments of the disclosure by persons skilled in the art without departing from the scope as defined by the appended claims.

The terms used throughout the specification and the appended claims are to be construed as “open-ended” terms. For example, the term “include” and its grammatical variants are intended to be non-limiting, such that recitation of items in a list is not to the exclusion of other like items that can be substituted or added to the listed items. The term “have” and its grammatical variants are intended to be non-limiting, such that recitation of items in a list is not to the exclusion of other like items that can be substituted or added to the listed items. Also, the singular forms “a”, “an”, and “the” used in the specification and the appended claims include plural references unless expressly and unequivocally limited to one referent.

What is claimed is:

1. A method of forming a semiconductor thin film, the method comprising:
forming, on a substrate, a thin film that contains one of Ge, Si, and a SiGe mixture, and Sn in a content of 0.1 atomic % or more to 20 atomic % or less; and
applying pulsed laser light to the thin film.

2. The method of forming the semiconductor thin film according to claim 1, wherein the applying of the pulsed laser light to the thin film transforms the thin film from an amorphous phase to a polycrystalline phase.

3. The method of forming the semiconductor thin film according to claim 1, wherein the substrate comprises a glass substrate.

4. The method of forming the semiconductor thin film according to claim 2, wherein the substrate comprises a glass substrate.

5. The method of forming the semiconductor thin film according to claim 1, wherein the substrate includes one of a semiconductor integrated circuit and a semiconductor device.

6. The method of forming the semiconductor thin film according to claim 2, wherein the substrate includes one of a semiconductor integrated circuit and a semiconductor device.

7. The method of forming the semiconductor thin film according to claim 1, wherein the substrate includes one of polyethylene naphthalate, polyethylene terephthalate, polyimide, and polycarbonate.

8. The method of forming the semiconductor thin film according to claim 2, wherein the substrate includes one of polyethylene naphthalate, polyethylene terephthalate, polyimide, and polycarbonate.

9. The method of forming the semiconductor thin film according to claim 1, wherein the applying of the pulsed laser light to the thin film is performed under pure water.

10. The method of forming the semiconductor thin film according to claim 1, wherein a wavelength of the pulsed laser light is in a range from about 193 nanometers to about 532 nanometers.
